(19) United States
(12) Patent Application Publication
(10) Pub. No.: US 2012/0307545 A1
(43) Pub. Date: Dec. 6, 2012

(54) Interleaved Bit Line Architecture for 2T2C Ferroelectric Memories

(75) Inventors: Hugh P. McAdams, McKinney, TX (US); Scott R. Summerfelt, Garland, TX (US); Patrick M. Ndai, Dallas, TX (US)

(73) Assignee: TEXAS INSTRUMENTS INCORPORATED, Dallas, TX (US)

(21) Appl. No.: 13/150,885

(22) Filed: Jun. 1, 2011

(51) Int. Cl. G11C 11/22

(52) U.S. Cl. 365/145; 365/149

(57) ABSTRACT

A ferroelectric memory with interleaved pairs of ferroelectric memory cells of the two-transistor, two-capacitor (2T2C) type. Each memory cell in a given pair is constructed as first and second portions, each portion including a transistor and a ferroelectric capacitor. Within each pair, a first portion of a second memory cell is physically located between the first and second portions of the first memory cell. As a result, complementary bit lines for adjacent columns are interleaved with one another. Each sense amplifier is associated with a multiplexer, so that the adjacent columns of the interleaved memory cells are supported by a single sense amplifier. Noise coupling among the bit lines is reduced, and the sense amplifiers can be placed along one side of the array, reducing the number of dummy cells required to eliminate edge cell effects.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

This invention is in the field of solid-state memories as realized in semiconductor integrated circuits. Embodiments of this invention are more specifically directed to the construction of arrays of ferroelectric memory cells in such memories.

Conventional metal-oxide-semiconductor (MOS) and complementary MOS (CMOS) logic and memory devices are prevalent in modern electronic devices and systems, as they provide an excellent combination of fast switching times and low power dissipation, along with their high density and suitability for large-scale integration. As is fundamental in the art, however, those devices are essentially volatile, in that logic and memory circuits constructed according to these technologies do not retain their data states upon removal of bias power. Especially in mobile and miniature systems, the ability to store memory and logic states in a non-volatile fashion is very desirable. As a result, various technologies for constructing non-volatile devices have been developed in recent years.

A recently developed technology for realizing non-volatile solid-state memory devices involves the construction of capacitors in which the dielectric material is a polarizable ferroelectric material, such as lead zirconate titanate (PZT) or strontium-bismuth-tantalate (SBT). Hysteresis in the charge-vs.-voltage (Q-V) characteristic, based on the polarization state of the ferroelectric material, enables the non-volatile storage of binary states in those capacitors. In contrast, conventional MOS capacitors lose their stored charge on power-down of the device. It has been observed that ferroelectric capacitors can be constructed by processes that are largely compatible with modern CMOS integrated circuits, for example placing capacitors above the transistor level, between overlying levels of metal conductors.

FIG. 1 illustrates an example of a Q-V characteristic of a conventional ferroelectric capacitor. As shown, the charge (Q) stored across the conductive plates depends on the voltage applied to the plates (V), and also on the recent history of that voltage. If the voltage V applied across the capacitor plates exceeds a “coercive” voltage +V_{α}, the capacitor polarizes into the “+1” state. According to this characteristic, once polarized to the “+1” state, so long as voltage V remains above coercive voltage −V_{β}, the capacitor exhibits a stored charge of +Q₁. Conversely, if the voltage V applied across the capacitor plates is more negative than coercive voltage −V_{β}, the capacitor is polarized into the “−1” state, and will exhibit a stored charge of −Q₂ for applied voltage V below +V_{α}.

An important characteristic of ferroelectric capacitors, for purposes of non-volatile storage in integrated circuits, is the difference in capacitance exhibited by a ferroelectric capacitor between its polarized states. As fundamental in the art, the capacitance of an element refers to the ratio of stored charge to applied voltage. In the context of a ferroelectric capacitor, the change in polarization state that occurs upon application of a polarizing voltage is reflected in charge storage. For example, referring to FIG. 1, the polarization of a ferroelectric capacitor from its “−1” state to its “+1” state is reflected in a relatively high capacitance C(−1), by way of which polarization charge involved in the change of polarization state is retained within the capacitor as the voltage exceeds its coercive voltage V_{α}; on the other hand, a capacitor already in its “+1” state exhibits little capacitance C(+1) due to polarization, since its ferroelectric domains are already aligned prior to the application of the voltage. In each case, the ferroelectric capacitor also has a linear capacitance, by virtue of its construction as parallel plates separated by a dielectric film (i.e., the ferroelectric material). As will be evident from the following description, a stored logic state is read by interrogating the capacitance of ferroelectric capacitors to discern its polarized state.

Ferroelectric technology is now utilized in on-volatile solid-state read/write random access memory (RAM) devices. These memory devices, commonly referred to as “ferroelectric RAM”, or “FeRAM”, or “FRAM” devices, are now commonplace in many electronic systems, particularly portable electronic devices and systems. FRAMs are especially attractive in implantable medical devices, such as pacemakers and defibrillators.

One approach to the implementation of FRAMs is the two-transistor, two-capacitor (2T2C) ferroelectric memory cell. FIG. 2 schematically illustrates memory cell 2_{j,k} of conventional 2T2C construction, which resides in a row j and a column k of a memory array. Memory cell 2_{j,k} includes two ferroelectric capacitors 4T, 4C, and two metal-oxide semiconductor (MOS) transistor 5T, 5C. Ferroelectric capacitors 4T, 4C are parallel-plate capacitors with ferroelectric material, such as PZT, as the dielectric; one or both of the plates may be formed in semiconductor material (e.g., a diffused region in the substrate, polysilicon, etc.) or in a metal or conductive metal compound material (e.g., a silicide, or conductive nitride). One plate of each of ferroelectric capacitors 4T, 4C is connected to plate line PLⱼ for row j. The other plate of ferroelectric capacitor 4T is connected to bit line BLTₖ for column k via the source/drain path of p-channel transistor 5T; similarly, the second plate of ferroelectric capacitor 4C is connected to bit line BLCₖ via the source/drain path of p-channel transistor 5C. The gates of transistors 5T, 5C are driven by word line WLⱼ* for row j of the memory array (the * indicating active low).

In operation, ferroelectric capacitors 4T, 4C store complementary polarization states that are reflected as a differential voltage or current at bit lines BLTₖ, BLCₖ when read. As such, a write operation to conventional memory cell 2_{j,k} consists of complementary levels applied to bit lines BLTₖ, BLCₖ while word line WLⱼ* is driven active low to turn on transistors 5T, 5C; a pulse at plate line PLⱼ during this state causes opposite polarization voltages to be applied across capacitors 4T, 4C relative to one another, and thus writing complementary polarization states. In a read operation, bit lines BLTₖ, BLCₖ are precharged to a selected voltage and then float, after which word line WLⱼ* is asserted active low. A pulse at plate line PLⱼ then causes the polarization states of capacitors 4T, 4C to be reflected at bit lines BLTₖ, BLCₖ, respectively, for sensing and amplification by sense amplifier 6ₖ for column k.

The conventional 2T2C arrangement, such as shown in FIG. 2 for memory cell 2_{j,k}, has been observed to provide good long term data retention in a form that can be efficiently realized, considering the relatively small area consumed by each memory cell. However, it has been observed, in connection with this invention, that the realization of a full memory array of 2T2C memory cells, in combination with corresponding sense amplifiers, is becoming difficult as device feature sizes continue to shrink.

FIG. 3a illustrates, in block form, a simplified arrangement of conventional memory array 5 of memory cells 2 such as constructed according to FIG. 2. Of course, memory arrays in actual integrated circuits are much larger than that shown in FIG. 3a; this small (4 by 4) example is provided for illustration only. In array 5 of FIG. 3a, each row of cells 2 in the array are associated with a corresponding one of word lines WL₀ through WL₃ and one of plate lines PL₀ through PL₃. Each column of cells 2 share a pair of bit lines, with column 0 coupled to bit lines BLT₀, BLC₀; column 1 coupled to bit lines BLT ₁, BLC₁, and so on. Sense amplifier 6₀ receives bit lines BLT₀, BLC₀, sense amplifier 6₁ receives bit lines BLT₁, BLC₁, sense amplifier 6₂ receives bit lines BLT₂, BLC₂, and sense amplifier 6₃ receives bit lines BLT₃, BLC₃. Accordingly, the energizing of word line WLⱼ and plate line PLⱼ for row j of cells 2 will cause the read or write (as the case may be) of data from or to cells 2_{j,0} through 2_{j,3}, via bit lines pairs BLT₀, BLC₀ through BLT₃, BLC₃, respectively.

It has been observed, in connection with this invention, that bit line switching noise can readily couple between bit lines of adjacent columns. As known in the art, a signal transition of one polarity occurring at one bit line in a closely-packed memory array can couple to an adjacent bit line for a neighboring column; if that adjacent bit line is making a transition of the opposite polarity, the induced noise from its neighbor can cause a data error. For example, noise from a high-to-low transition at bit line BLC₀ from the access of cell 2_{j,0} in a read operation can couple to and disturb a low-to-high transition occurring on an adjacent bit line BLT₁ from the access of its cell 2_{j,1} at the same time. This noise-coupling problem is exacerbated with shrinking memory cell sizes, because of the corresponding reduction in signal strength from the smaller memory cells, and because of the close proximity of adjacent bit lines to one another. As such, conventional 2T2C memory arrays are necessarily constructed using the well-known “twisted bit line” arrangement, such as described for static RAMs in commonly assigned U.S. Pat. No. 4,980,860, incorporated herein by reference, in which the switching noise is coupled as common mode noise to adjacent differential bit lines. This bit line twisting of course complicates the layout of the memory array, and consumes chip area.

Another limitation encountered in modern 2T2C ferroelectric memories involves the layout constraints on sense amplifier circuitry. As known in the art, the circuitry required for a conventional sense amplifier will occupy a chip area of a width (in the orientation of FIG. 3a) that is necessarily wider than that of a single column of memory cells 2. In the typical conventional arrangement of FIG. 3a, each sense amplifier 6 occupies the width of a pair of memory cells 2, with sense amplifier 6₀ as wide as the space occupied by columns 0 and 1 (i.e., cells 2_{j,0} and 2_{j,1} for rows j=0 to 3). But since both columns require a sense amplifier 6, sense amplifiers 6 must reside on both opposing sides of array 5, with those on one side sensing odd-numbered columns and those on the other side sensing even-numbered columns. In this case, sense amplifiers 6₀, 6₂ are placed below array 5 in FIG. 3a, while sense amplifiers 6₁, 6₃ are placed above array 5.

FIG. 3b illustrates the layout of a conventional FRAM memory including several arrays 5 arranged in this manner. Each array 5 may include multiple partitions of memory cells, if desired for the particular addressing scheme and as described in commonly assigned and copending U.S. patent application Ser. No. 12/699,357, filed Feb. 3, 2010, incorporated herein by this reference. In this example, word line drivers 7 are located along one side of arrays 5, and drive individual word lines that each extend along a row of memory cells 2 over multiple arrays 5 in the horizontal direction (in the orientation of FIG. 3b). Each array 5 is associated with a corresponding set of plate line drivers 8, each driving a plate line for a corresponding row of memory cells 2. In this example, each array 5 is associated with a set of plate line drivers 8 disposed along one of its vertical edges (in the orientation of FIG. 3b). And, in the manner described above in connection with FIG. 3a, the necessarily larger pitch required for realization of sense amplifiers 6 requires two sets of sense amplifiers 6, disposed on opposing sides (top and bottom in this orientation) of each array 5, one of each supporting odd-numbered and even-numbered bit line pairs as described above.

As is fundamental in the art, it is desirable from a cost standpoint to realize integrated circuit functions in as little chip area as possible. In the case of solid-state memory arrays, this desire is reflected in the use of minimum feature size elements to realize the memory array, considering that memory arrays can occupy a large portion of the entire integrated circuit chip area, even in larger-scale integrated logic circuits with embedded memory functions. However, proximity effects in the photolithography of sub-micron features (e.g., transistor gates) can cause significant variations in the formation of such features in memory cells at the edges of regular arrays, as compared with the same features in memory cells in the array interior. As such, many modern integrated memory circuits are constructed to have several “dummy” memory cell structures around each edge of a regular array of structures that is adjacent to circuitry of a different structure, such as around each edge of memory arrays 5 adjacent to sense amplifiers 6, word line drivers 7, and plate line drivers 8 in the arrangement of FIG. 3b. These dummy cell features are not electrically connected or active in the operation of the memory, but absorb the proximity effects, allowing all “live” memory cells to be patterned properly.

An additional array edge failure mechanism is present in ferroelectric memories. It has been observed, in connection with the invention, that the ferroelectric capacitors of memory cells at the edges of arrays generally exhibit a higher defect density than do capacitors in the interior of the arrays. These defects are reflected in degraded data retention performance (i.e., degraded non-volatility) for these edge cells. It is believed that these increased edge cell defects are caused by hydrogen from the ambient atmosphere during fabrication being absorbed by the ferroelectric material, such as PZT, in capacitors at the array edge to a greater extent than by capacitors in the array interior. As such, the number of dummy ferroelectric memory cells required at the edges of arrays 5, where adjacent to non-ferroelectric circuitry, must comprehend this additional edge effect. It has been observed that the chip area required for such ferroelectric dummy cells can be as much as five to ten percent of the array area, for memory arrays of modern construction and memory size.

### BRIEF SUMMARY OF THE INVENTION

Embodiments of this invention provide a non-volatile solid-state memory of the two-transistor, two-capacitor ferroelectric type in which coupling among bit lines of adjacent columns is reduced.

Embodiments of this invention provide such a memory in which the number of sacrificial ferroelectric cells along edges of memory arrays can be reduced.

Embodiments of this invention provide such a memory that is compatible with large-scale partitioned ferroelectric memories including local input/output lines.

Other objects and advantages of embodiments of this invention will be apparent to those of ordinary skill in the art having reference to the following specification together with its drawings.

Embodiments of this invention may be implemented into a ferroelectric memory of the two-transistor, two-capacitor ferroelectric type. Each column of memory cells is associated with complementary or differential bit lines. Memory cells in adjacent columns are interleaved with one another so that the nearest neighbor to each bit line is associated with an adjacent column. For each 2T2C memory cell, the two ferroelectric capacitors are separated from one another by a ferroelectric capacitor associated with a memory cell in an adjacent column, with each ferroelectric capacitor coupled to an associated bit line via an access transistor for that column. In some embodiments, local input/output lines running parallel to the bit lines are inserted between adjacent bit lines, providing a shielding effect and thus reducing coupling among the bit lines.

According to another aspect of the invention, the interleaved bit lines in the ferroelectric memory cells are multiplexed prior to application to a sense amplifier. This arrangement allows the sense amplifier for a given pair of columns to be realized within a two-column pitch, yet residing on a single side of the memory array. Memory arrays may thus be placed adjacent to one another, reducing the requirement for sacrificial “dummy” edge cells on each array.

### BRIEF DESCRIPTION OF THE SEVERAL VIEWS OF THE DRAWING

FIG. 1 is a plot of a charge-vs.-voltage characteristic of a conventional ferroelectric capacitor.

FIG. 2 is an electrical diagram, in schematic form, of a conventional non-volatile static random access memory (SRAM) cell of the two-transistor, two-capacitor (2T2C) ferroelectric type.

FIG. 3a is an electrical diagram, in block form, and FIG. 3b is a plan layout view, of a non-volatile ferroelectric memory.

FIG. 4 is an electrical diagram, in block form, illustrating the architecture of a ferroelectric random access memory (FRAM) according to embodiments of this invention.

FIGS. 5a and 5b are electrical diagrams, in block and schematic form, of a pair of FRAM cells in a memory array block, illustrating the construction and operation of the FRAM of FIG. 4 according to embodiments of the invention.

FIG. 6 is a cross-sectional view of a portion of an integrated circuit illustrating the construction of an FRAM cell in the FRAM of FIG. 4, according to embodiments of the invention.

FIGS. 7a through 7c are plan layout views of an interleaved pair of FRAM cells in the FRAM of FIG. 4, according to embodiments of this invention.

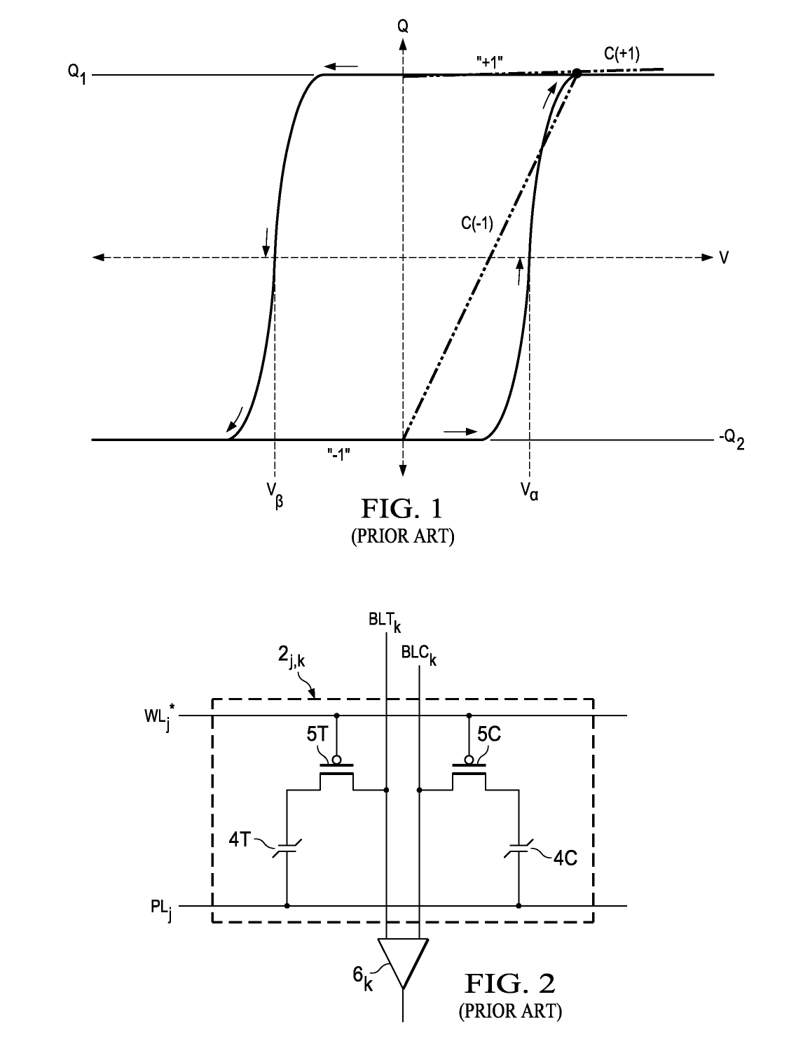

### DETAILED DESCRIPTION OF THE INVENTION

This invention will be described in connection with its embodiments, namely as implemented into an integrated circuit incorporating one or more arrays of ferroelectric random access memory (RAM) cells, as it is contemplated that this invention is especially beneficial in such an application. It is also contemplated that this invention may provide important benefits in other types of integrated circuits. Accordingly, it is to be understood that the following description is provided by way of example only, and is not intended to limit the true scope of this invention as claimed.

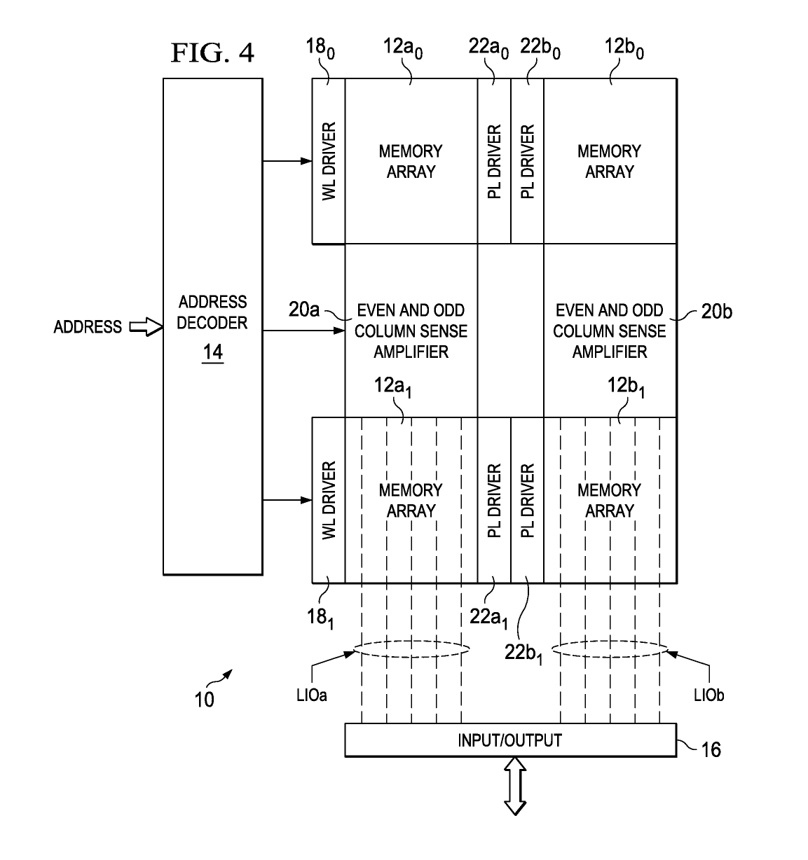

FIG. 4 illustrates the architecture of memory 10 constructed according to embodiments of this invention. In this example, memory 10 is shown as a stand-alone ferroelectric memory device (i.e., constructed as an FRAM). It is also contemplated that memory 10 may alternatively be integrated into a large-scale logic device such as a microprocessor, single-chip microcomputer, or a so-called “system-on-a-chip”. It is contemplated that those skilled in the art having reference to this specification will be readily able to realize memory 10 in such a larger-scale integrated circuit if desired, without undue experimentation.

In memory 10 according to embodiments of this invention, each memory cell is constructed as a two-transistor, two-capacitor (2T2C) ferroelectric random access memory cell such as described above in connection with FIG. 2. These memory cells (not shown in FIG. 4) are arranged in rows and columns within multiple memory array blocks 12. In the arrangement shown in FIG. 4, memory array blocks 12 are arranged into two sectors and two segments, the sectors and segments being orthogonal to one another. Memory array block 12a₀ resides in sector “0” and segment “a”; memory array block 12a₁ resides in sector “1” and segment “a”; memory array block 12b₀ resides in sector “0” and segment “b”; and memory array block 12b₁ resides in sector “1” and segment “b”. Each memory array block 12 may be further partitioned, internally to that memory array block 12, as known in the art.

A memory address directed to memory 10 is received and decoded by address decoder 14, in this architecture of FIG. 4. As typical in the art, address decoder 14 considers the received address as having a row portion and a column portion. The row portion of the memory address selects a row of memory cells within memory 10, each row being within a single sector and multiple segments. The column portion of the memory address selects one or more columns of memory cells associated with a memory array block 12 within the selected sector of memory 10. In this 2T2C arrangement, each column corresponds to a pair of complementary bit lines that are coupled to one or more memory cells in that column and in the selected row.

In this arrangement, memory array blocks 12a₀ and 12b₀ in sector “0” share word lines driven by word line driver 18₀, each word line coupled to memory cells within an associated row, and selectable by address decoder 14 based on the row portion of the received address. Similarly, memory array blocks 12a₁ and 12b₁ in sector “1” share word lines driven by word line driver 18₁. In each case, word lines driven by word line drivers 18₀, 18₁ effectively extend across all memory array blocks 12 that reside in the same sector. Because memory 10 is an FRAM, memory array blocks 12a₀, 12b₀, are associated with plate line driver circuits 22a₀, 22b₀, respectively, and memory array blocks 12a₁, 12b₁, are associated with plate line driver circuits 22a₁, 22b₀, respectively. Plate line driver circuits 22 apply the appropriate voltages to the plate electrodes of the selected FRAM cells to carry out the desired read or write operation, as known in the art. In this implementation, plate line driver circuits 22 are disposed between memory array blocks 12, as shown.

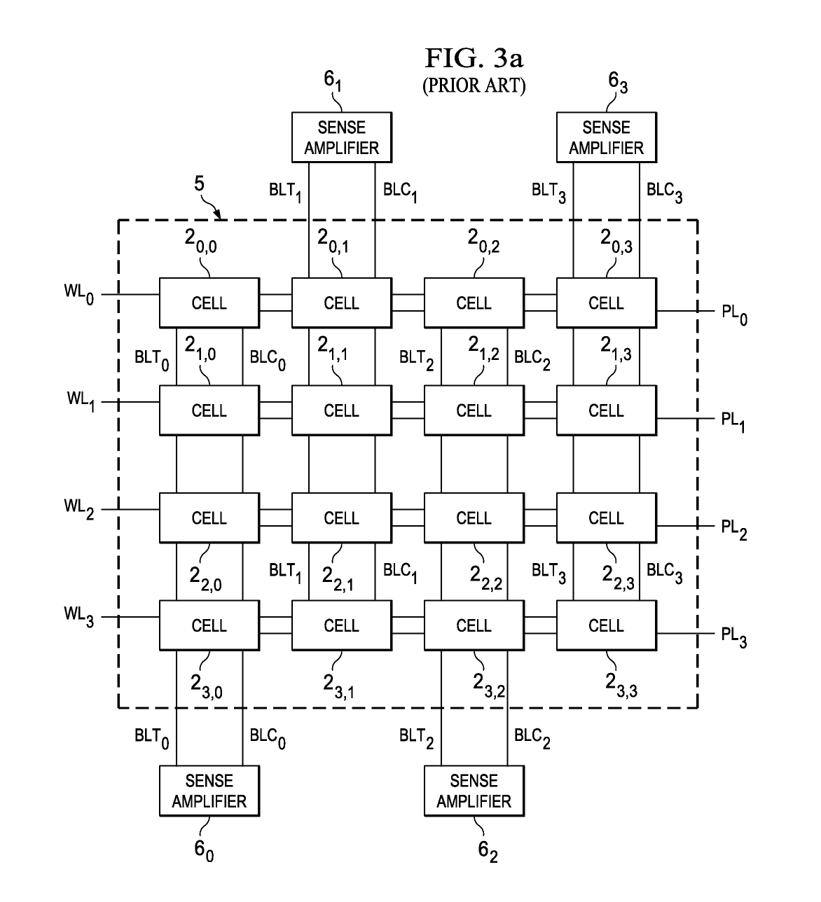

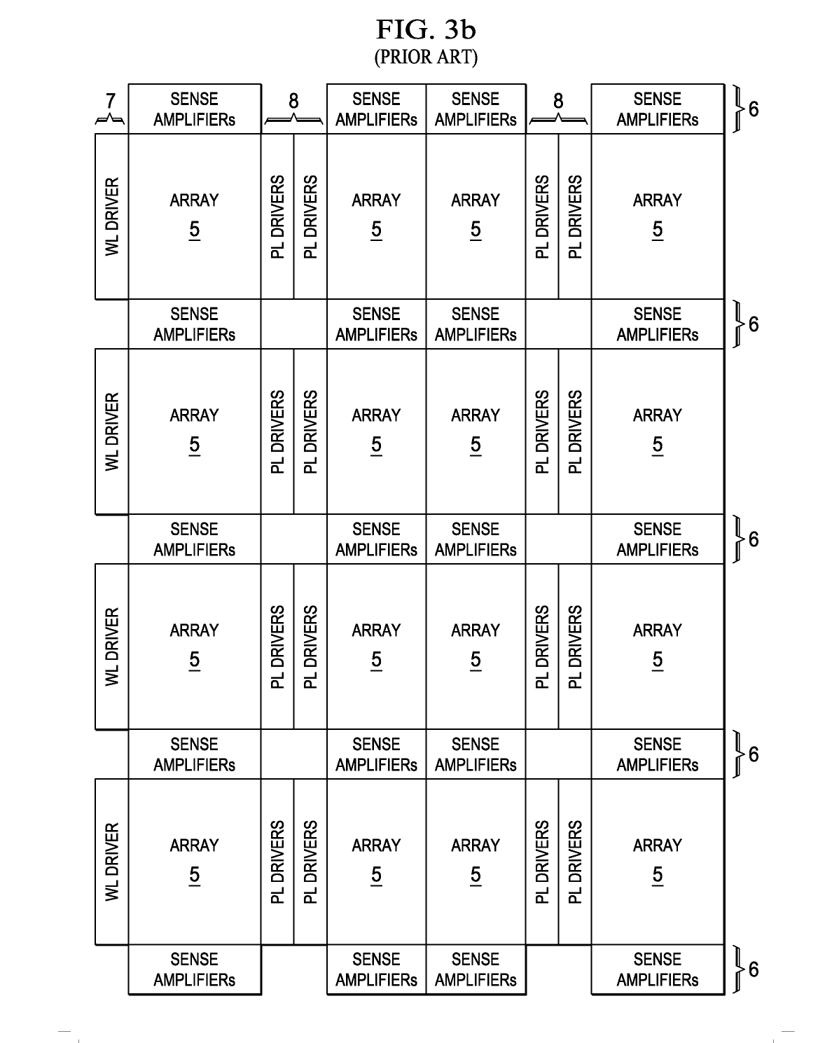

In the column direction, each memory array block 12 is associated with a corresponding bank of sense amplifiers 20. In contrast to the conventional arrangement described above in connection with FIGS. 3a and 3b, and according to embodiments of this invention, a single bank of sense amplifiers 20 is provided for both the even and odd columns in each memory array block 12, and can be placed on a single end of that memory array block 12 as shown in FIG. 4. In this example, in which two memory array blocks 12a₀, 12a₁ reside in the same segment of memory 10, a single sense amplifier bank 20a can be placed between and associated with memory array blocks 12a₀, 12a₁. Similarly, sense amplifier bank 20b is placed between and associated with memory array blocks 12b₀, 12b₁, which reside in the same segment of memory 10. Because sense amplifier banks 20 can be placed between memory array blocks 12 within each memory segment, this arrangement will save significant chip area in the realization of memory 10.

In the architecture of memory 10, as is typical in memories of similar architecture, only a single sector is addressed in each cycle, and thus requires access to global input/output function 16. Accordingly, the memory array blocks 12a₀, 12a₁ in segment “a” share a set of local input/output lines LIOa, and memory array blocks 12b₀, 12b₁ in segment “b” share local input/output lines LIOb. Local input-output lines LIO communicate data between input/output function 16 and corresponding sense amplifiers 20. In this example, each sense amplifier 20 is supported by a complementary pair of local input/output lines LIO. Multiplexers may be provided within input/output function 16, for selecting the appropriate local input/output lines LIO for communication with circuitry external to memory 10, as typical in the art.

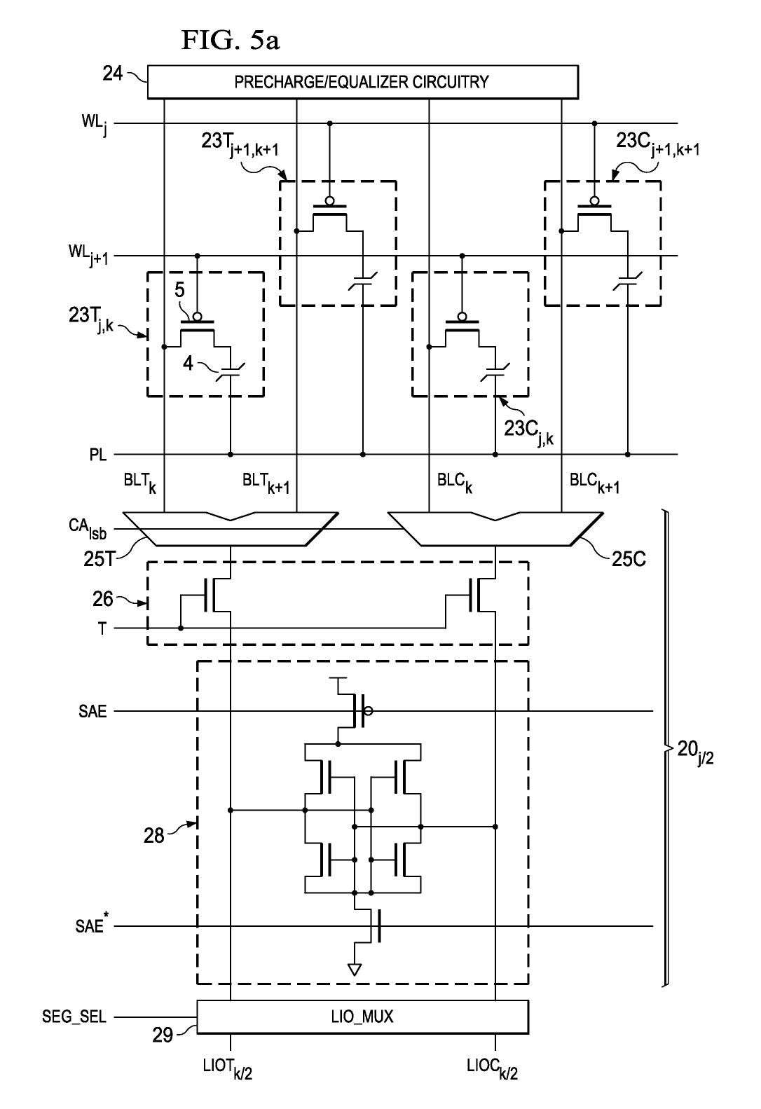

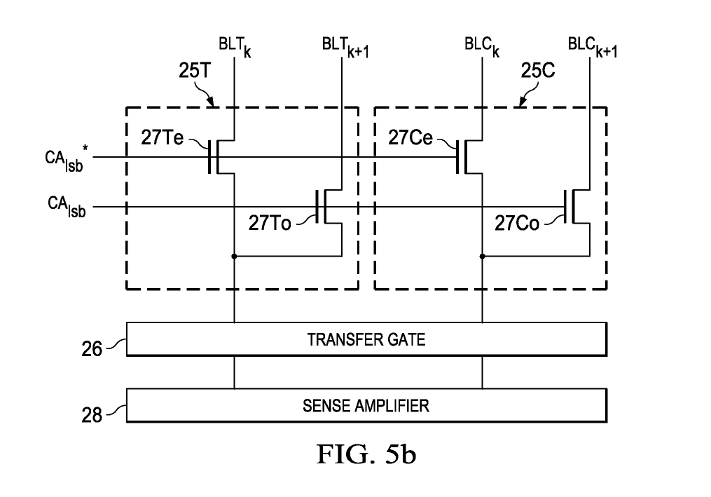

FIG. 5a illustrates the electrical arrangement of a representative pair of 2T2C FRAM cells and associated sense circuitry in one of memory array blocks 12 of memory 10, for purposes of illustration of embodiments of this invention. In this example, FRAM cells 23_{j,k} and 23_{j-1,k+1} are illustrated as arranged in an interleaved fashion with one another. In this example, FRAM cell 23_{j,k} is associated with row j and column k of memory array block 12, and FRAM cell 23_{j+1,k+1} is associated with row j+1 and column k+1. As shown in FIG. 5a, and as will be described in further detail below, cell 23_{j,k} is arranged in two portions 23T_{j,k}, 23C_{j,k}, each with one transistor 5 and one capacitor 4 and connected to bit lines BLTₖ, BLCₖ, respectively. Cell 23_{j+1,k+1} is similarly arranged in two portions 23T_{j+1,k-1}, 23C_{j+1,k+1}, each with one transistor 5 and one capacitor 4 and connected to bit lines BLTₖ₊₁, BLCₖ₊₁, respectively. According to embodiments of this invention, FRAM cells 23_{j,k} and 23_{j+1,k+1} are interleaved with one another, such that cell portion 23T_{j+1,k+1} is disposed between cell portions 23T_{j,k}, 23C_{j,k}, with bit line BLTₖ₊₁ placed between bit lines BLTₖ, BLCₖ. As such, cell portion 23C_{j,k} is disposed between cell portions 23T_{j+1,k+1}, 23C_{j+1,k+1}, so that bit line BLCₖ is between bit lines BLTₖ₊₁, BLCₖ₊₁. The benefits of this arrangement will be described in further detail below.

In this example, FRAM cell 23_{j,k} receives word line WLⱼ from word line drivers 18, and FRAM cell 23ⱼ₊₁ receives word line WLⱼ. An active level at word line WLⱼ turns on the transistors 5 in each of the cells 23 in its row j; transistors 5 may be either n-channel (as shown) or p-channel transistors, with the active level of word line WLⱼ being high or low accordingly. In addition to receiving their corresponding word lines WLⱼ, WLⱼ₊₁ from word line drivers 18, FRAM cells 23_{j,k}, 23_{j+1,k+1} receive plate line voltages from plate line drivers 22 on plate line PL, which is common to cells 23 in rows j and j+1, in the conventional manner. Of course, memory array block 12 will include many more cells 23 similarly arranged as shown in FIG. 5a, and arranged in more than the two rows and columns shown in that Figure with corresponding word lines WL, plate lines PL, and bit lines BLT, BLC.

As known in the art for 2T2C FRAMs, bit lines BLT, BLC carry complementary data levels in a write operation, and as such the two ferroelectric capacitors within each cell 23 are polarized to opposite states to differentially define the stored data state. To accomplish this complementary operation, bit line precharge and equalization circuitry 24 is coupled to each complementary pair of bit lines BLT, BLC, to precharge each bit line to a reference potential, such as ground, in advance of a read or write operation, and to equalize bit lines in each pair with one another. Of course, other precharge voltages may be used if desired. Precharge and equalization circuitry 24 may be constructed in the conventional manner.

According to embodiments of this invention, columns k and k+1 share a single instance of sense amplifier circuitry within the bank of sense amplifiers 20 associated with its memory array block 12. As such, the number of instances of sense amplifier circuitry within each bank 20 is one-half the number of columns in the associated memory array block 12. In the example shown in FIG. 5a, sense amplifier circuitry 20_{k/2} is illustrated as supporting columns k and k+1, in a multiplexed fashion. Sense amplifier circuitry 20_{k/2} (for the case in which k is an even number) includes multiplexer 25T, which receives bit lines BLTₖ, BLTₖ₊₁, at its inputs, and multiplexer 25C, which receives bit lines BLCₖ, BLCₖ₊₁, at its inputs. Multiplexers 25T, 25C receive least significant column address bit CA_{1sb} from address decoder 14, and as such select between bit lines BLTₖ, BLCₖ (for an even column address) and bit lines BLTₖ₊₁, BLCₖ₊₁ (for an odd column address). The outputs of multiplexers 25T, 25C are coupled to the cross-coupled nodes of sense amplifier 28 via transfer gates 26, responsive to transfer control signal T.

Sense amplifier 28 is a conventional differential sense amplifier constructed of cross-coupled CMOS inverters with “head” and “tail” control transistors, as well known in the art. As such, sense amplifier 28 is capable of amplifying a differential at its cross-coupled nodes, upon receiving active levels at its control signals SAE, SAE*. The cross-coupled nodes of sense amplifier 28 are coupled to local input/output multiplexer 29, and in response to the segment of memory array block 12 being selected (by segment select signal SEG_SEL), are coupled to complementary local input/output lines LIOT_{k/2}, LIOC_{k/2}.

FIG. 5b illustrates an example of the construction of multiplexers 25T, 25C according to embodiments of this invention. In this example, multiplexers 25T, 25C are realized effectively as pass gates between bit lines BLT, BLC of each column and shared transfer gate 26. Multiplexer 25T includes n-channel transistor 27Tc connected on one side of its source/drain path to bit line BLTₖ (for the even column), and n-channel transistor 27To connected on one side of its source/drain path to bit line BLTₖ₊₁ (for the odd column). The opposite sides of the source/drain paths of transistors 27Te, 27To are connected in common, to transfer gate 26 as shown. Transistor 27Te receives column address bit CA_{1Sb}* at its gate, so as to be turned on (conductive) in response to the least significant bit of the column address being low (or “0”, indicating selection of an even-numbered column). Conversely, transistor 27To receives column address bit CA_{1sb} at its gate, so as to be turned on in response to the least significant column address bit active high, indicating selection of an odd-numbered column. Multiplexer 25C is constructed in similar fashion, including transistors 27Ce, 27Co connected to bit lines BLTₖ₋₁, BLCₖ₊₁, respectively; these transistors 27Ce, 27Co also receive column address bits CA_{1Sb}*, CA_{1sb} at their gates, respectively, for controlling application of the selected bit line to transfer gate 26. According to this construction, because multiplexers 25T, 25C are constructed as pass gates, their operation is the same in both read and write operations.

As suggested by FIG. 5b, this arrangement of multiplexers 25T, 25C in connection with sense amplifier 28 and the bit line pairs for columns k and k+1 illustrate that the use of multiplexers 25T, 25C enable a single instance of sense amplifier 28 to be shared by these two columns. As such, the chip area allowed for each single instance of sense amplifier 28 is the space required for two columns (i.e., in the row direction). As discussed above, this placement of sense amplifiers within two column pitches is consistent with conventional construction, except that conventional memories sense amplifiers for even and odd columns in different banks, on either side of the memory array (see FIGS. 3a and 3b). An important benefit of embodiments of this invention is provided by the multiplexing of bit line pairs for adjacent columns into a single instance of sense amplifier 28, because sense amplifier banks 21 need only be placed on one side of each memory array block 12.

In this regard, it is further contemplated that a single instance of sense amplifier 28 may support two columns in each of two memory array blocks 12, if sense amplifier banks 21 are placed between adjacent memory array blocks 12 where those memory array blocks 12 are in different sectors (only one of which will be selected in a given memory cycle). This arrangement is illustrated in the architecture of FIG. 4, as described above. In this case, separate multiplexers 25 will be required for each memory array block 12.

In operation, prior to a read operation, bit line precharge and equalization circuitry 24 (FIG. 5a) precharges and equalizes bit lines BLTₖ, BLCₖ with one another, and bit lines BLTₖ₋₁, BLCₖ₊₁ with one another, at or near the desired precharge voltage. To read FRAM cell 23_{j,k}, for example, word line WLⱼ and PLⱼ are driven to the desired read levels (e.g., with plate line PL pulsed above a ferroelectric transition voltage), such that the current ferroelectric state of the two capacitors within cell 23_{j,k} defines a differential charge or voltage across bit lines BLTₖ, BLCₖ. Cell 23_{j-1,k+1} meanwhile remains in its previously-written state, as its word line WLⱼ₊₁ remains inactive low. In a read of cell 23_{j,k}, the received column address will be have an even-numbered value. As such, multiplexers 25T, 25C will couple bit lines BLTₖ, BLCₖ to transfer gate 26. Upon control signal T then coupling bit lines BLTₖ, BLCₖ to the sense nodes of sense amplifier 28, activation of control signals SAE, SAE* will cause sense amplifier 28 to amplify and latch the differential bit line state. After amplification, and in response to segment select signal SEG_SEL, local input/output multiplexer 29 will couple the sense nodes of sense amplifier 28 to local I/O lines LIOT_{k/2}, LIOC_{k/2}, for communication to global input/output circuit 16 (FIG. 4).

Write operations are performed in a similar manner, with the input data state to be written to the addressed cell 23_{j,k} of this memory array block 12 established by global input/output circuit 16 and appearing at local I/O lines LIOT_{k/2}, LIOC_{k/2}. Local input/output multiplexer 29 will apply this differential state to the cross-coupled nodes of sense amplifier 28, and active control signals SAE, SAE*, allow sense amplifier 28 to establish and latch a full differential signal at its sense nodes. Transfer gate 26 and multiplexers 25T, 25C apply this latched differential state onto bit lines BLTₖ, BLCₖ for addressed column k while via bit line precharge and equalization circuitry 24 remains off to allow bit lines BLTₖ, BLCₖ to attain the desired differential level. This differential level establishes the polarization state within the cell 23 within the row that receives the appropriate write levels on word line WLⱼ and the corresponding plate line PLⱼ, in the conventional manner.

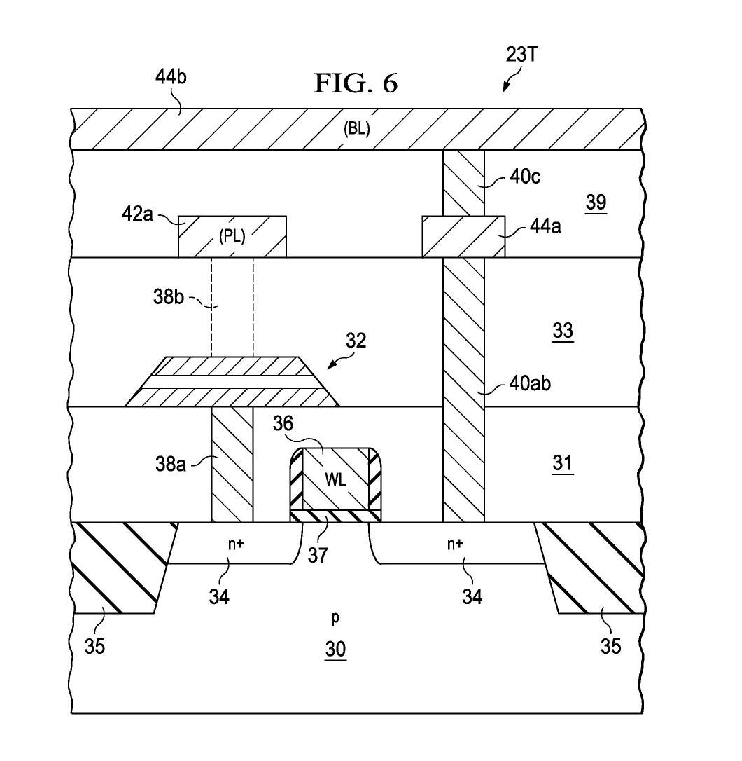

FIG. 6 illustrates, in cross-section, the construction of an example of cell portion 23T as realized in an integrated circuit according to the arrangement of FIG. 4; cell portions 23C will be similarly constructed (although perhaps in a reverse orientation). In this cross-sectional realization, word line WL is realized in polysilicon element 36, and extends into and out of the page, and plate line PL is realized in first level metal element 42a and extends into and out of the page (i.e., parallel with word line WL, both elements being associated with rows of FRAM cells 23). Bit line BL is realized in second level metal element 44b, and extends orthogonally to word line WL and plate line PL. Transistor 5 is realized at the surface of p-type substrate 30 (or well), at an active region disposed between isolation dielectric structures 35 (formed by shallow trench isolation in this example). N+ source/drain regions 34 are formed into substrate 30 on opposing sides of polysilicon element 36 in a self-aligned manner, thus forming transistor 5. Bit line BL in second level metal element 44b is electrically connected to one of source/drain regions 34 by way of via 40c through dielectric film 39, first level metal pad 44a, and via 40ab through dielectric films 31, 33. All vias 38, 40 in this example are formed of a conductive material, such as tungsten or another metal or conductive metal compound.

Ferroelectric capacitor 4 in cell portion 23T is formed by ferroelectric stack 32, which in this example is a “sandwich” stack of conductive plates (such as element metal, or a conductive metal compound such as a nitride or silicide) between which ferroelectric material such as PZT is disposed. Typically, as known in the ferroelectric integrated circuit art, stack 32 is formed by the sequential deposition of the conductive and ferroelectric materials, etched to the desired dimensions by a single stack etch. In this example, stack 32 is present at the top surface of first level dielectric film 31 overlying polysilicon element 36 forming word line WL. The bottom conductive plate of stack 32 is connected to the opposite source/drain region 34 (opposite from that in connection with bit line BL) of transistor 4 by via 38a through dielectric film 31. Plate line PL in first level metal element 42a contacts the top conductive plate of stack 32 by via 38b through dielectric film 33.

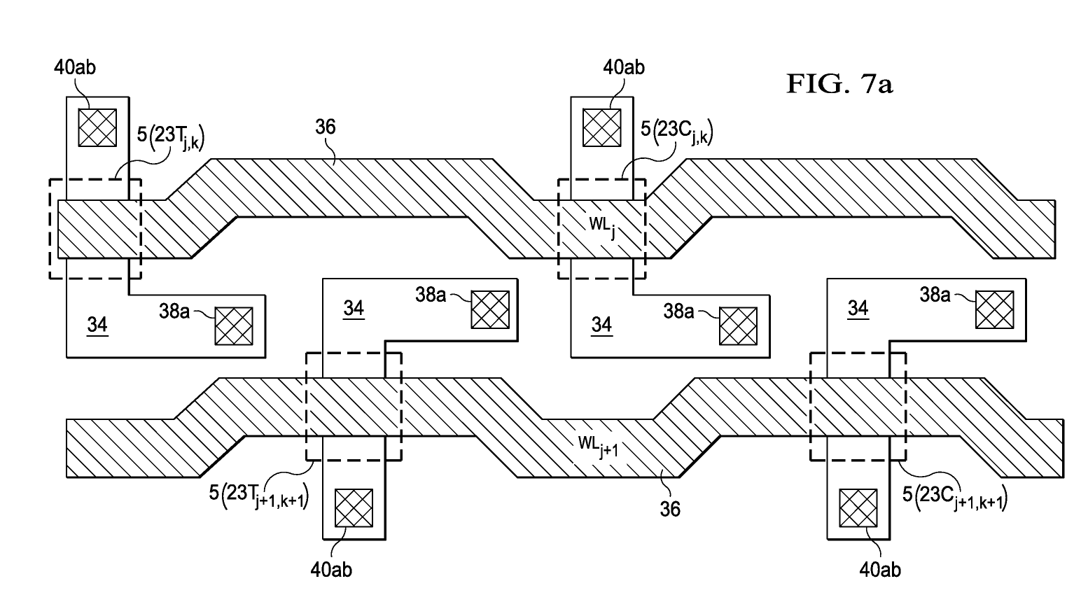

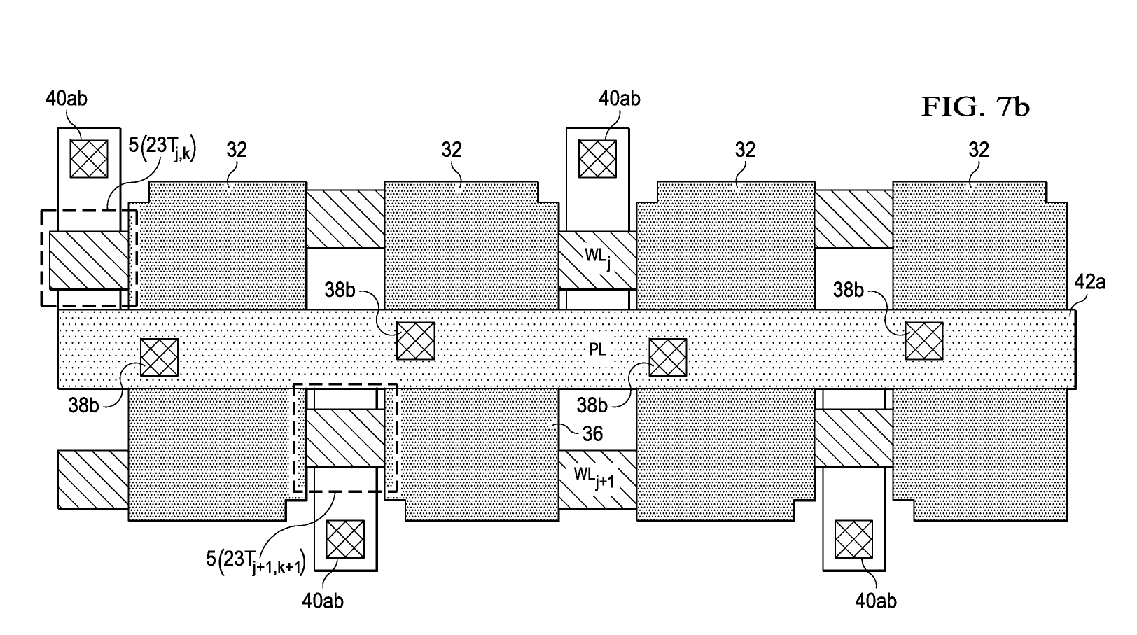

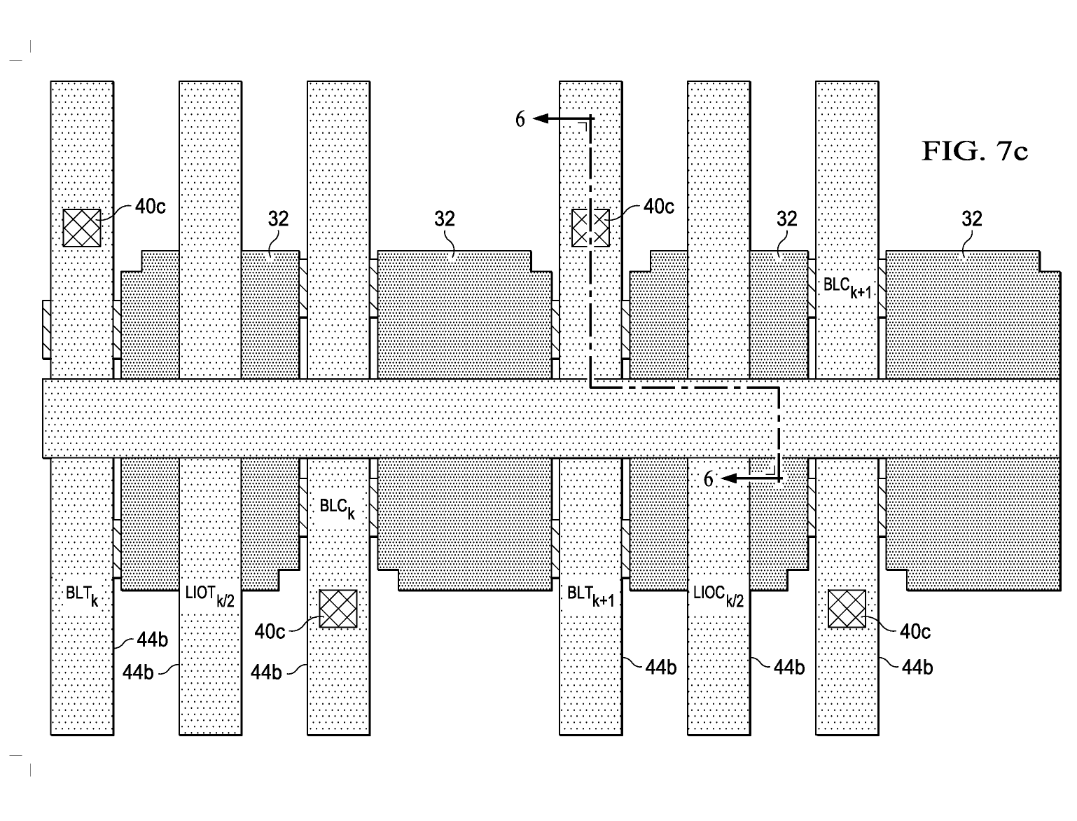

FIGS. 7a through 7c illustrate, in plan view, the layout of interleaved FRAM cells 23_{j,k}, 23_{j+1,k+1} according to embodiments of this invention, and constructed in the manner described above relative to FIG. 6. For purposes of this description, FRAM cell 23_{j,k} includes two portions 23T_{j,k}, 23C_{j,k}, with portion 23T_{j,k} including one ferroelectric capacitor 4 that is coupled by one transistor 5 to bit line BLTₖ when selected via word line WLⱼ, and portion 23C_{j,k} including one ferroelectric capacitor 4 that is coupled by one transistor 5 to bit line BLCₖ, also when selected via word line WLⱼ. Similarly, FRAM cell 23_{j+1,k+1} includes portions 23T_{j+1,k+1}, 23C_{j-1,k+1} that include one capacitor 4 and one transistor 5 each, and that are coupled to bit lines BLTₖ₊₁, BLCₖ₊₁, respectively, in response to word line WLⱼ₊₁.

FIG. 7a illustrates the partial construction of FRAM cells 23_{j,k}, 23_{j+1,k+1} at the polysilicon (gate) and active (source/drain) levels. In this interleaved 2T2C construction, four transistors 5 are evident in the arrangement of FIG. 7a, each with its source/drain regions 34 in an active region and a gate electrode in a polysilicon element 36. For example, transistor 5 for cell portion 23T_{j,k} is illustrated in the upper left-hand portion of FIG. 7a by a dashed region, at the location of source-drain regions 34 crossed by polysilicon element 36 that serves as word line WLⱼ. Word line WLⱼ continues, in an instance of polysilicon element 36, also serving as the gate electrode for transistor 5 in cell portion 23C_{j,k}. Similarly, the instance of polysilicon element 36 serving as word line WLⱼ₊₁ crosses active regions containing source/drain regions 34 for transistors 5 in cell portions 23T_{j+1,k+1}, 23C_{j+1,k+1}. Each of the active regions for transistors 5 of these cell portions 23T_{j,k}, 23C_{j,k}, 23T_{j+1,k+1}, 23C_{j+1,k+1} include contact location 38a for making electrical contact between its transistor 5 and the appropriate one of bit lines BLTₖ, BLCₖ, BLTₖ₊₁, BLCₖ₊₁, and contact location 40ab for making the electrical connection between its transistor 5 and its capacitor 4.

FIG. 7b illustrates the structure of FRAM cells 23_{j,k}, 23_{j+1,k+1} at a later point in its manufacture, after the formation of ferroelectric stacks 32 that serve as capacitors 4 in these two cells. As shown in FIG. 7b, for example, ferroelectric stack 32 for cell portion 23T_{j,k} is disposed between the transistors 5 for cell portions 23T_{j,k}, 23T_{j-1,k+1}, residing above polysilicon elements 36 for word lines WLⱼ, WLⱼ₊₁. The other ferroelectric stacks 32 are similarly arranged, as shown. Each ferroelectric stack 32 makes contact to source/drain region 32 of transistor 5 for its corresponding cell portion via contact 38a (not shown in FIG. 7b). First level metal element 42a serving as plate line PL runs parallel with (but above) word lines WLⱼ, WLⱼ₊₁. While not visible, contact location 38b are illustrated at the top of each ferroelectric stack 32 shown in FIG. 7b, illustrating the location of the electrical connection to overlying plate line PL in first level metal element 42a. In this example, contact locations 38a, 38b do not overlap one another (i.e., are not stacked with one another at the same location), as shown.

In FIG. 7c, the structure is illustrated at a later point in its manufacture, after the deposition and patterning of first level metal elements 42a, and second level metal elements 44b. To the extent visible in FIG. 7c, first level metal elements 42a serving as a contact “pad” in the connection to the top plate of each ferroelectric stack 32 is visible; as evident from the cross-sectional view of FIG. 6, these first level metal elements 42a are in a lower level of metal than are second level metal elements 44b. Second level metal elements 44c run “north-south” in FIG. 7c, and overlie the cell portions 23T_{j,k}, 23j,k, 23T_{j+1,k+1}, 23C_{j+1,k+1} in this example. One second level metal element 44b makes contact to the source/drain region 34 of transistor 5 in cell portion 23T_{j,k} through via location 40c, and serves as bit line BLTₖ. Another second level metal element 44b makes contact to the source/drain region 34 of transistor 5 in cell portion 23T_{j 1,k+1} through via location 40c, and serves as bit line BLTₖ₊₁. Similarly, an instance second level metal element 44b contact to the source/drain region 34 of transistor 5 in cell portion 23C_{j,k} through via location 40c, and serves as bit line BLCₖ; another instance of second level metal element 44b makes contact to the source/drain region 34 of transistor 5 in cell portion 23C_{j+1,k+1} through via location 40c, and serves as bit line BLCₖ₊₁. The connection between these bit lines BLT, BLC and their underlying pass transistor 5 source/drain regions 34 is made through corresponding first level metal pads 44a (not visible in FIG. 7c), as shown in FIG. 6.

In addition, local input/output lines LIOT_{k/2}, LIOC_{k/2} are also formed by second level metal elements 44b in this same metal level as bit lines BLT, BLC. Local input/output lines LIOT_{k/2}, LIOC_{k/2} run parallel to bit lines BLT, BLC, and overlie ferroelectric stacks 32 in some locations (separated from the top plates by dielectric film 33 shown in FIG. 6). In the arrangement of FIG. 7c, local input/output line LIOT_{k/2} is placed between bit lines BLTₖ and BLTₖ₊₁, while local input/output line LIOC_{k/2} is placed between bit lines BLCₖ and BLCₖ₊₁. And as evident from FIG. 7c, a significant space of on the order of a second level metal pitch is left between bit lines BLCₖ, BLTₖ₊₁ overlying ferroelectric capacitor 5 for cell portion 23C; no local input/output line is placed in that space.

Referring back to FIG. 4, it is contemplated that each of memory array blocks 12 in memory 10 are constructed in the manner described above relative to FIGS. 6 and 7a through 7c. As described above, because sense amplifiers 28 are associated with adjacent columns of interleaved memory cells, such as those described above relative to FIGS. 5a and 7a through 7c, each instance of sense amplifier 28 may be placed within the width of a pair of interleaved memory cells within the two adjacent corresponding columns. This realization of sense amplifiers 28 within this two-column pitch can be carried out in the conventional manner, considering that current-day conventional FRAM memories are constructed in this manner as described above in connection with FIGS. 3a and 3b. But according to embodiments of this invention, multiplexers 25T, 25C allow these adjacent columns to share a single instance of sense amplifiers 28, which allows one-half as many sense amplifiers 28 as the number of columns, to support the entire memory array block 12. Indeed, as described above in connection with FIG. 5b, this single bank 20 of sense amplifiers can support a memory array block 12 on either side, assuming that the supported memory array blocks 12 are in different sectors of memory 10. In any case, because a single bank 20 of sense amplifiers can support its memory array block 12, that bank 20 can reside on a single side of its memory array block 12 as shown in FIG. 4. Pairs of memory array blocks 12 can thus be placed adjacent to one another as shown in FIG. 4 (e.g., memory array blocks 12a₀ and 12a₁ of FIG. 4) without requiring sense amplifier circuitry therebetween. The regularity of the FRAM cell 23 layout can thus continue between memory array blocks 12 in that direction, eliminating the need for “dummy” FRAM cells structures serving as sacrificial “edge” cells that protect the actual FRAM cells 23 from degraded ferroelectric reliability and photolithographic proximity effects, as necessary in modern memory devices.

As evident from this description, the interleaving of FRAM cell portions among one another in the memory array results in an interleaved arrangement of bit lines as shown in FIGS. 5a and 7c, and in some embodiments enables the placement of local input/output lines within those interleaved bit lines as shown in FIG. 7c. This interleaving results in substantial reduction in coupling among these bit lines and local input/output lines, without requiring bit line “twisting” within the memory array, as required in conventional cell layouts. For the example of the two columns illustrated in FIG. 7c, no two individual bit lines BLTₖ, BLCₖ, BLTₖ₊₁, BLCₖ₊₁ are placed immediately adjacent to one another. Some pairs of adjacent bit lines are separated by a substantial distance (e.g., bit lines BLCₖ and BLTₖ₊₁), which of course reduces the coupling of switching noise from one to the other. Other pairs of adjacent bit lines have a local input/output line therebetween (e.g., local input/output line LIOT_{k/2} placed between bit lines BLTₖ, BLTₖ₊₁). But local input/output lines LIOT_{k/2}, LIOC_{k/2} are not active during cell access or the sensing portion of the memory cycle, as these lines receive their signal after the amplification by sense amplifier 28 of the sensed data state (in read cycles), or prior to memory cell access (in write cycles). In either case, the DC level at local input/output lines LIOT_{k/2}, LIOC_{k/2} effectively shield each of adjacent bit lines BLTₖ, BLTₖ₊₁; BLTₖ, BLTₖ₊₁, respectively, within a pair from switching noise occurring on the other. As mentioned above, these results enable the close placement of bit lines within a memory array of 2T2C FRAM cells 23, with excellent sensing performance and without requiring bit line twists within the array.

In addition, the interleaving of FRAM cells as described above, and according to embodiments of this invention, in combination with multiplexing of bit lines from adjacent columns into a single sense amplifier, allows for the placement of each sense amplifier circuit within the bit cell space provided for (effectively) two 2T2C FRAM cells. This sense amplifier space is the same as allowed in conventional FRAM memories, but in this case banks of sense amplifiers need only be provided on one side of each memory array block, as described above relative to FIG. 4 in connection with embodiments of the invention. In FRAM memories that include multiple array blocks, again as described above in connection with FIG. 4, the freeing-up of one side of each array block allows neighboring memory array blocks to be placed adjacent to one another. As a result, the necessity of “dummy” FRAM cells along all four edges of memory array blocks to reduce edge cell degradation of the ferroelectric material, as well as to reduce cell variation due to photolithographic proximity effects, is eliminated because the edge cells of the adjacent memory array blocks are identical to one another, such that these edge effects are not present in the first place. The chip area savings attained by eliminating these dummy cells can be as much as 5% of the memory array area, depending on the memory size.

Accordingly, the arrangement of 2T2C FRAM cells according to embodiments of this invention not only provides improved electrical performance due to the shielding of coupling noise, but also reduces the chip area required for realization of the FRAM function. This chip area reduction is due to elimination of the need for bit line twists, and also due to elimination of dummy cells from at least one edge of each memory array block.

While this invention has been described according to its embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

What is claimed is:

1. A ferroelectric memory array comprised of two-transistor, two-capacitor ferroelectric memory cells arranged in rows and columns, and arranged as a plurality of pairs of adjacent memory cells, each pair of memory cells comprising:
a first memory cell associated with a first column, comprising:
first and second ferroelectric capacitors, each having a first plate coupled to a plate line, and having a second plate;
a first access transistor having a conduction path connected between the second plate of the first ferroelectric capacitor and a first bit line of the first column, the first access transistor connected to a word line; and
a second access transistor having a conduction path connected between the second plate of the first ferroelectric capacitor and a second bit line of the first column, the first access transistor connected to a word line; and
a second memory cell associated with a second column, comprising:
first and second ferroelectric capacitors, each having a first plate coupled to a plate line, and having a second plate;
a first access transistor having a conduction path connected between the second plate of the first ferroelectric capacitor and a first bit line of the second column, the first access transistor connected to a word line; and
a second access transistor having a conduction path connected between the second plate of the first ferroelectric capacitor and a second bit line of the second column, the first access transistor connected to a word line;
wherein the first and second bit lines of the first and second columns are parallel to one another;
wherein the first ferroelectric capacitor and the first access transistor of the second memory cell is disposed between the first and second ferroelectric capacitors of the first memory cell, so that the first bit line of the second column is disposed between the first and second bit lines of the first column;
and wherein the second ferroelectric capacitor and the second access transistor of the first memory cell is disposed between the first and second ferroelectric capacitors of the second memory cell, so that the second bit line of the first column is disposed between the first and second bit lines of the second column.

2. The memory array of claim 1, further comprising:
a plurality of sense amplifiers, each associated with a pair of columns of memory cells; and
a plurality of multiplexers, each associated with one of the sense amplifiers, each multiplexer having inputs receiving the first and second bit lines from each of its associated pair of columns, having outputs coupled to complementary inputs of its associated sense amplifier, and having select inputs receiving control signals corresponding to a column address;
wherein each multiplexer is controlled, responsive to its select inputs, to selectively couple the first and second bit lines from one of its associated pair of columns, or the first and second bit lines from the other of its associated pair of columns, to the complementary inputs of its associated sense amplifier.

3. The memory array of claim 2, wherein each of the plurality of sense amplifiers is coupled to a local input/output line extending across the array in a direction parallel with the bit lines of each column;
and wherein, within each pair of memory cells, a local input/output line is disposed between one of the bit lines for the first column and one of the bit lines for the second column.

4. The memory array of claim 2, wherein each of the plurality of sense amplifiers is coupled to a complementary pair of local input/output lines extending across the array in a direction parallel with the bit lines of each column;
and wherein, within each pair of memory cells, a first one of a pair of local input/output lines is disposed between the first bit line for the first column and one of the bit lines for the second column, and a second one of the pair of local input/output lines is disposed between the first bit line for the second column and one of the bit lines for the first column.

5. The memory array of claim 1, wherein the gates of the first and second transistor for the first memory cell of each pair are connected to a word line for a first row;
and wherein the gates of the first and second transistor for the second memory cell of each pair are connected to a word line for a second row adjacent to the first row.

6. An array of ferroelectric memory cells at a surface of a semiconductor body, the memory cells arranged in rows and columns within a first memory array block, each memory cell including two portions, each portion including a transistor and a ferroelectric capacitor, the memory cells arranged in interleaved pairs, each interleaved pair of memory cells comprising:
first and second active regions for first and second portions, respectively, of a first memory cell;
first and second active regions for first and second portions, respectively, of a second memory cell, the first portion of the second memory cell disposed at the surface between the first and second portions of the first memory cell of the pair;
a first polysilicon element disposed over the first and second active regions of the first and second portions of the first memory cell, the first polysilicon element defining source/drain regions in each of the first and second active regions on either side thereof;
a second polysilicon element disposed over the first and second active regions of the first and second portions of the second memory cell, the second polysilicon element defining source/drain regions in each of the first and second active regions on either side thereof;
a first ferroelectric capacitor in connection with, and overlying at least a portion of, one of the source/drain regions of the first active region of the first memory cell;
a second ferroelectric capacitor in connection with, and overlying at least a portion of, one of the source/drain regions of the second active region of the first memory cell;
a third ferroelectric capacitor in connection with, and overlying at least a portion of, one of the source/drain regions of the first active region of the second memory cell, the third ferroelectric capacitor disposed between the first and second ferroelectric capacitors;
a fourth ferroelectric capacitor in connection with, and overlying at least a portion of, one of the source/drain regions of the first active region of the second memory cell, so that the second ferroelectric capacitor is disposed between the third and fourth ferroelectric capacitors;
first true and complementary bit lines formed in metal conductors and parallel with one another, each in connection with and overlying at least a portion of the first and second active regions, respectively, of the first memory cell; and
second true and complementary bit lines formed in metal conductors and parallel with one another and with the first true and complementary bit lines, each of the second true and complementary bit lines in connection with and overlying at least a portion of the first and second active regions, respectively, of the second memory cell, the second true bit line disposed between the first true and complementary bit lines, and the first complementary bit line disposed between the second true and complementary bit lines.

7. The memory array of claim 6, further comprising:
a first bank of sense amplifiers associated with the first memory array block, each sense amplifier in the first bank of sense amplifiers associated with first true and complementary bit lines for a first column of memory cells, and with second true and complementary bit lines for a second column of memory cells, the first and second column of memory cells adjacent to one another and associated with first and second memory cells in a corresponding column of interleaved pairs of memory cells.

8. The memory array of claim 7, wherein the first bank of sense amplifiers is disposed on a single side of the first memory array block.

9. The memory array of claim 8, further comprising a second memory array block of memory cells arranged in rows and columns; each memory cell including two portions, each portion including a transistor and a ferroelectric capacitor, the memory cells arranged in interleaved pairs, each interleaved pair of memory cells comprising:
first and second active regions for first and second portions, respectively, of a first memory cell;
first and second active regions for first and second portions, respectively, of a second memory cell, the first portion of the second memory cell disposed at the surface between the first and second portions of the first memory cell of the pair;
a first polysilicon element disposed over the first and second active regions of the first and second portions of the first memory cell, the first polysilicon element defining source/drain regions in each of the first and second active regions on either side thereof;
a second polysilicon element disposed over the first and second active regions of the first and second portions of the second memory cell, the second polysilicon element defining source/drain regions in each of the first and second active regions on either side thereof;
a first ferroelectric capacitor in connection with, and overlying at least a portion of, one of the source/drain regions of the first active region of the first memory cell;
a second ferroelectric capacitor in connection with, and overlying at least a portion of, one of the source/drain regions of the second active region of the first memory cell;
a third ferroelectric capacitor in connection with, and overlying at least a portion of, one of the source/drain regions of the first active region of the second memory cell, the third ferroelectric capacitor disposed between the first and second ferroelectric capacitors;
a fourth ferroelectric capacitor in connection with, and overlying at least a portion of, one of the source/drain regions of the first active region of the second memory cell, so that the second ferroelectric capacitor is disposed between the third and fourth ferroelectric capacitors;
first true and complementary bit lines formed in metal conductors and parallel with one another, each in connection with and overlying at least a portion of the first and second active regions, respectively, of the first memory cell; and
second true and complementary bit lines formed in metal conductors and parallel with one another and with the first true and complementary bit lines, each of the second true and complementary bit lines in connection with and overlying at least a portion of the first and second active regions, respectively, of the second memory cell, the second true bit line disposed between the first true and complementary bit lines, and the first complementary bit line disposed between the second true and complementary bit lines;
a second bank of sense amplifiers associated with the second memory array block, each sense amplifier in the second bank of sense amplifiers associated with first true and complementary bit lines for a first column of memory cells, and with second true and complementary bit lines for a second column of memory cells, the first and second column of memory cells adjacent to one another and associated with first and second memory cells in a corresponding column of interleaved pairs of memory cells;
wherein the first and second memory arrays are disposed with adjacent edges with one another;
and wherein the second bank of sense amplifiers is disposed on a single side of the second memory array block, opposite the side of the first memory array block at which the first bank of sense amplifiers is disposed.

10. The memory array of claim 6, wherein the first polysilicon element serves as a word line for a first row of memory cells;
and wherein the second polysilicon element serves as a word line for a second row of memory cells adjacent to the first row of memory cells.

11. A non-volatile memory of the ferroelectric type, comprising:
address decoder circuitry, for driving one of a plurality of word lines responsive to a received memory address;
input/output circuitry, for receiving input data to be written to a selected memory cell and for presenting output data read from a selected memory cell;
a first memory array, comprised of two-transistor, two-capacitor ferroelectric memory cells arranged in rows and columns, and arranged as a plurality of pairs of adjacent memory cells, each pair of memory cells comprising:
a first memory cell associated with a first column, comprising:
first and second ferroelectric capacitors, each having a first plate coupled to a plate line, and having a second plate;
a first access transistor having a conduction path connected between the second plate of the first ferroelectric capacitor and a first bit line of the first column, the first access transistor connected to a word line; and
a second access transistor having a conduction path connected between the second plate of the first ferroelectric capacitor and a second bit line of the first column, the first access transistor connected to a word line; and
a second memory cell associated with a second column, comprising:
first and second ferroelectric capacitors, each having a first plate coupled to a plate line, and having a second plate;
a first access transistor having a conduction path connected between the second plate of the first ferroelectric capacitor and a first bit line of the second column, the first access transistor connected to a word line; and
a second access transistor having a conduction path connected between the second plate of the first ferroelectric capacitor and a second bit line of the second column, the first access transistor connected to a word line;
wherein the first and second bit lines of the first and second columns are parallel to one another;
wherein the first ferroelectric capacitor and the first access transistor of the second memory cell is disposed between the first and second ferroelectric capacitors of the first memory cell, so that the first bit line of the second column is disposed between the first and second bit lines of the first column;
and wherein the second ferroelectric capacitor and the second access transistor of the first memory cell is disposed between the first and second ferroelectric capacitors of the second memory cell, so that the second bit line of the first column is disposed between the first and second bit lines of the second column;
a first plurality of sense amplifiers, each associated with a pair of columns of memory cells in the first memory array and disposed on one side of the first memory array; and
a first plurality of multiplexers, each associated with one of the first plurality of sense amplifiers, each multiplexer having inputs receiving the first and second bit lines from each of its associated pair of columns, having outputs coupled to complementary inputs of its associated sense amplifier, and having select inputs receiving control signals corresponding to a column address from the address decoder circuitry, to selectively couple the first and second bit lines from one of its associated pair of columns, or the first and second bit lines from the other of its associated pair of columns, to the complementary inputs of its associated sense amplifier.

12. The memory of claim 11, further comprising:
a second memory array, comprised of two-transistor, two-capacitor ferroelectric memory cells arranged in rows and columns, and arranged as a plurality of pairs of adjacent memory cells, the second memory array disposed adjacent the first memory array on a side of the first memory array opposite the first plurality of sense amplifiers.

13. The memory of claim 12, wherein each pair of memory cells in the second memory array comprise:
a first memory cell associated with a first column, comprising:
first and second ferroelectric capacitors, each having a first plate coupled to a plate line, and having a second plate;
a first access transistor having a conduction path connected between the second plate of the first ferroelectric capacitor and a first bit line of the first column, the first access transistor connected to a word line; and
a second access transistor having a conduction path connected between the second plate of the first ferroelectric capacitor and a second bit line of the first column, the first access transistor connected to a word line; and
a second memory cell associated with a second column, comprising:
first and second ferroelectric capacitors, each having a first plate coupled to a plate line, and having a second plate;
a first access transistor having a conduction path connected between the second plate of the first ferroelectric capacitor and a first bit line of the second column, the first access transistor connected to a word line; and
a second access transistor having a conduction path connected between the second plate of the first ferroelectric capacitor and a second bit line of the second column, the first access transistor connected to a word line;
wherein the first and second bit lines of the first and second columns are parallel to one another;
wherein the first ferroelectric capacitor and the first access transistor of the second memory cell is disposed between the first and second ferroelectric capacitors of the first memory cell, so that the first bit line of the second column is disposed between the first and second bit lines of the first column;
and wherein the second ferroelectric capacitor and the second access transistor of the first memory cell is disposed between the first and second ferroelectric capacitors of the second memory cell, so that the second bit line of the first column is disposed between the first and second bit lines of the second column.

14. The memory of claim 13, further comprising:
a second plurality of sense amplifiers, each associated with a pair of columns of memory cells in the second memory array and disposed on one side of the second memory array; and
a second plurality of multiplexers, each associated with one of the second plurality of sense amplifiers, each multiplexer having inputs receiving the first and second bit lines from each of its associated pair of columns, having outputs coupled to complementary inputs of its associated sense amplifier, and having select inputs receiving control signals corresponding to a column address from the address decoder circuitry, to selectively couple the first and second bit lines from one of its associated pair of columns, or the first and second bit lines from the other of its associated pair of columns, to the complementary inputs of its associated sense amplifier.
wherein the second plurality of sense amplifiers is disposed adjacent a side of the second memory array opposite the first memory array.

15. The memory of claim 11, further comprising:
a plurality of word line drivers, each coupled to gate electrodes of the first and second access transistors of memory cells in a row of the first memory array;
wherein the first and second memory cells in each of the pairs of adjacent memory cells are associated with adjacent rows of memory cells in the first memory array.

16. The memory of claim 11, further comprising:
a plurality of plate line drivers, each coupled to the second plate of the first and second ferroelectric capacitors of memory cells in a row of the first memory array.

17. The memory of claim 11, wherein each of the first plurality of sense amplifiers is coupled to a local input/output line extending across the first memory array in a direction parallel with the first and second bit lines of each column;
and wherein, within each pair of memory cells, a local input/output line is disposed between one of the bit lines for the first column and one of the bit lines for the second column.

18. The memory of claim 17, wherein each of the first plurality of sense amplifiers is coupled to a complementary pair of local input/output lines extending across the array in a direction parallel with the bit lines of each column;
and wherein, within each pair of memory cells, a first one of a pair of local input/output lines is disposed between the first bit line for the first column and one of the bit lines for the second column, and a second one of the pair of local input/output lines is disposed between the first bit line for the second column and one of the bit lines for the first column.
